(19) United States
(12) Patent Application Publication
(10) Pub. No.: US 2008/0308876 A1
(43) Pub. Date: Dec. 18, 2008

(54) Semiconductor device and method of manufacturing the same

(76) Inventors: Hye-Lan Lee, Hwaseong-si (KR); Si-Young Choi, Seongnam-si (KR); Sang-Bom Kang, Seoul (KR); Si-Hyung Lee, Suwon-si (KR); Sang-Jin Hyun, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/155,969

(22) Filed: Jun. 12, 2008

(30) Foreign Application Priority Data
Jun. 12, 2007 (KR) 10-2007-0057450

(51) Int. Cl. H01L 27/092; H01L 21/8238

(52) U.S. Cl. 257/369; 438/199; 257/E21.632; 257/E27.062

(57) ABSTRACT

A semiconductor device includes a first gate structure on a first region of a substrate, the first gate structure including sequentially formed a first insulating layer pattern, a first conductive layer pattern, and a first polysilicon layer pattern doped with first impurities of a first conductivity type, a first source/drain in the first region of the substrate doped with second impurities of a second conductivity type, a second gate structure on a second region of the substrate, the second gate structure including sequentially formed a second insulating layer pattern, a second conductive layer pattern, and a second polysilicon layer pattern doped with third impurities with the first conductivity type, and a second source/drain in the second region of the substrate doped with fourth impurities having a conductivity type opposite the second conductivity.

### BACKGROUND OF THE INVENTION

1. Field of the Invention

Example embodiments of the present invention relate to a semiconductor device and to a method of manufacturing the same. More particularly, example embodiments of the present invention relate to a complementary metal-oxide-semiconductor (CMOS) device having a gate electrode including polysilicon and to a method of manufacturing the same.

2. Description of the Related Art

As information technologies develop, e.g., computers, mobile communication devices, and so forth, structures of components thereof, e.g., semiconductors, may require reduced weight, miniaturized size, and high performance, i.e., ultra-high speed function with ultra-low power consumption. In other words, semiconductors may require an increased degree of integration in order to provide improved function. For example, a transistor of a semiconductor may require reduced length of a gate thereof and/or a reduced thickness of a gate oxide layer thereof.

A reduced length of the gate, however, may cause a short channel effect, and a reduced thickness of the gate oxide layer may increase current leakage and may deteriorate on/off characteristics of the transistor. Further, reducing the length of the gate and/or thickness of the gate oxide layer may be limited physically. Thus, attempts have been made to replace the gate oxide layer with a gate insulating layer including high-K materials. Formation of a polysilicon layer pattern directly on an insulation layer including high-K materials, e.g., HfSiON, however, may trigger occurrence of the Fermi level pinning phenomenon due to bonding between, e.g., hafnium (Hf) in the gate insulating layer, and, e.g., silicon in a polysilicon layer pattern, thereby raising threshold voltage. While threshold voltage may be controlled, e.g., in a DRAM device having a greater threshold voltage in a memory cell area of a transistor than in a logic circuit area, by a channel ion implantation process and/or a dual metal gate manufacturing process, such processes may be complicated and may reduce reliability and operability of the semiconductors.

For example, forming a gate by the channel ion implantation process, i.e., using doped polysilicon, may cause penetration of P-type impurities, e.g., boron (B), from the gate into the substrate or into the gate insulating layer, and may trigger formation of a depletion region in the gate. In another example, forming dual metal gate, i.e., wet etching metals having work functions suitable for an N-type metal-oxide-semiconductor (NMOS) transistor and a P-type metal-oxide-semiconductor (PMOS) to form a step difference therebetween, may be difficult.

### SUMMARY OF THE INVENTION

Example embodiments of the present invention are therefore directed to a semiconductor device and to a method of manufacturing the same, which substantially overcome one or more of the disadvantages and shortcomings of the related art.

It is therefore a feature of an embodiment of the present invention to provide a semiconductor device having a structure capable of minimizing a depletion region in a gate thereof and reducing penetration of impurities from the gate into a substrate.

It is another a feature of an embodiment of the present invention to provide a method of manufacturing a semiconductor device having a structure capable of minimizing a depletion region in a gate thereof and reducing penetration of impurities from the gate into a substrate.

At least one of the above and other conductivity type, a second gate structure on a second region of the substrate, features and advantages of the present invention may be realized by providing a semiconductor device, including a first gate structure on a first region of a substrate, the first gate structure including a first insulating layer pattern on the substrate, a first conductive layer pattern on the first insulating layer pattern, and a first polysilicon layer pattern on the first conductive layer pattern, the first polysilicon layer pattern including first impurities of a first conductivity type, a first source/drain in the first region of the substrate, the first source/drain including second impurities of a second the second gate structure including a second insulating layer pattern on the substrate, a second conductive layer pattern on the second insulating layer pattern, the second conductive layer pattern including a substantially same material as the first conductive layer pattern, and a second polysilicon layer pattern on the second conductive layer pattern, the second polysilicon layer pattern including third impurities with the first conductivity type, and a second source/drain in the second region of the substrate, the second source/drain including fourth impurities having a conductivity type opposite the second conductivity.

The first and second conductive layer patterns may exhibit a work function in a range of about 4.3 eV to about 4.7 eV. The first and second conductive layer patterns may include a metal. The first and second conductive layer patterns may include titanium (Ti), tungsten (W), tantalum (Ta), or rubidium (Ru). The first and second conductive layer patterns may include a metal silicide. The first and second conductive layer patterns may include tantalum nitride (TaN), tungsten nitride (WN), titanium nitride (TiN), hafnium nitride (HfN), hafnium silicon nitride (HfsiN), titanium silicon nitride (TiSiN), tantalum silicon nitride (TaSiN), and hafnium aluminum nitride (HfAlN). A concentration of the first impurities in the first polysilicon layer may be different from a concentration of the third impurities in the second polysilicon layer pattern. The semiconductor may further include third and fourth conductive layer patterns on the first and second gate structures, respectively. The third and fourth conductive layer patterns may include a material having a lower resistance than a resistance of the first and second polysilicon layer patterns.

The first and second insulating layer patterns may include a substantially same material. The first and second insulating layer patterns may include silicon dioxide (SiO₂) and/or silicon oxynitride (SiON). The first and second insulating layer patterns may include hafnium oxide and/or zirconium oxide. The first and second insulating layer patterns may include one or more of hafnium oxide (HfO₂), hafnium oxynitride (HfON), hafnium silicon oxide (HfSiO), hafnium silicon oxynitride (HfSiON), hafnium aluminum oxide (HfAlO), hafnium aluminum oxynitride (HfAlON), hafnium lanthanum oxide (HflaO), hafnium lanthanum oxynitride (HfLaON), zirconium oxide (ZrO₂), zirconium oxynitride (ZrON), zirconium silicon oxynitride (ZrSiON), and zirconium silicon oxide (ZrSiO). The first and second insulating layer patterns may include a metal oxide, the metal oxide being a lanthanide. The first and second insulating layer patterns may include one or more of lanthanum oxide (La₂O₃), praseodymium oxide (Pr₂O₃), and dysprosium oxide (Dy₂O₃). The first and second insulating layer patterns may include one or more of lead zirconate titanate (Pb(ZrₓTi₁₋ₓ)O₃; PZT), bismuth lanthanum titanate (Bi₄₋ₓLaₓTi₃O₁₂; BLT), strontium bismuth tantalite (SrBi2Ta₂O₉; SBT), bismuth titanate (Bi₄Ti₃O₁₂; BIT), barium strontium titanate (Ba₁₋ₓSrₓTiO₃; BST), strontium bismuth barium tantalate (SrBi2Ta₂O₉; SBTN), and lead lanthanum zirconate-titanate ((Pb, La)(Zr, Ti)O₃; PLZT).

At least one of the above and other features and advantages of the present invention may be realized by providing a method of manufacturing a semiconductor device, the method including forming a first gate structure on a first region of a substrate, the first gate structure including sequentially stacked a first insulating layer pattern, a first conductive layer pattern, and a first polysilicon layer pattern, the first polysilicon layer pattern including first impurities of a first conductivity type, forming a first source/drain in the first region of the substrate, the first source/drain including second impurities of a second conductivity type, forming a second gate structure on a second region of the substrate, the second gate structure including sequentially stacked a second insulating layer pattern, a second conductive layer pattern having a substantially same material as the first conductive layer pattern, and a second polysilicon layer pattern, the second polysilicon pattern including third impurities of the first conductivity type, and forming a second source/drain in the second region of the substrate, the second source/drain including fourth impurities having a conductivity type opposite the second conductivity.

The method may further include forming on the first and second regions of the substrate an insulating layer, a conductive layer, and a polysilicon layer doped with the first impurities, partially etching the polysilicon layer, the conductive layer, and the insulating layer to form the first and second gate structures on the first and second regions of the substrate, respectively, the first gate structure having the first insulating layer pattern, the first conductive layer pattern, and the first polysilicon layer pattern, and the second gate structure having the second insulating layer pattern, the second conductive layer pattern, and the second polysilicon layer pattern, forming the first source/drain by doping the second impurities onto the first region of the substrate exposed by the first gate structure, and forming the second source/drain by doping the fourth impurities onto the second region of the substrate exposed by the second gate structure. The conductive layer may be formed to have a work function in a range of about 4.3 eV to about 4.7 eV. The conductive layer may be formed by a physical vapor deposition (PVD) process, a chemical vapor deposition (CVD) process, or an atomic layer deposition (ALD) process.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a cross-sectional view of a semiconductor device in accordance with an embodiment of the present invention;

FIG. 2 illustrates a cross-sectional view of a semiconductor device in accordance with another embodiment of the present invention;

FIG. 3 illustrates a cross-sectional view of a semiconductor device in accordance with another embodiment of the present invention; and

FIGS. 4-9 illustrate cross-sectional views of sequential stages in a method of manufacturing the semiconductor device illustrated in FIG. 1.

### DETAILED DESCRIPTION OF THE INVENTION

Korean Patent Application No. 10-2007-0057450, filed on Jun. 12, 2007, in the Korean Intellectual Property Office, and entitled: “Semiconductor Device and Method of Manufacturing the Same,” is incorporated by reference herein in its entirety.

Exemplary embodiments of the present invention will now be described more fully hereinafter with reference to the accompanying drawings, in which exemplary embodiments of the invention are illustrated. Aspects of the invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of elements, layers, and regions may be exaggerated for clarity of illustration. It will also be understood that when an element and/or layer is referred to as being “on” another element, layer and/or substrate, it can be directly on the other element, layer, and/or substrate, or intervening elements and/or layers may also be present. Further, it will be understood that the term “on” can indicate solely a vertical arrangement of one element and/or layer with respect to another element and/or layer, and may not indicate a vertical orientation, e.g., a horizontal orientation. In addition, it will also be understood that when an element and/or layer is referred to as being “between” two elements and/or layers, it can be the only element and/or layer between the two elements and/or layers, or one or more intervening elements and/or layers may also be present. Further, it will be understood that when an element and/or layer is referred to as being “connected to” or “coupled to” another element and/or layer, it can be directly connected or coupled to the other element and/or layer, or intervening elements and/or layers may be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include an nth member, where n is greater than 3, whereas the expression “at least one selected from the group consisting of A, B, and C” does not.

It will be understood that, although the terms, e.g., first, second, third, and so forth, are used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of embodiments of the present invention.

Spatially relative terms, such as “beneath,” “below,” “lower,” “above,” “upper” and the like, are used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures may be schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a semiconductor device and a method of manufacturing the same in accordance with some example embodiments of the present invention will be explained in detail with reference to the accompanying drawings.

FIG. 1 illustrates a cross-sectional view of a semiconductor device in accordance with an example embodiment of the present invention. Referring to FIG. 1, a semiconductor device 10 may include a substrate 100, a first transistor T1, and a second transistor T2.

The substrate 100 may be any suitable semiconductor substrate, e.g., a substrate including silicon or germanium, a silicon-on-insulator (SOI) substrate, or a germanium-on-insulator (GOI) substrate. The substrate 100 may include an isolation layer 102 to divide the substrate 100 into an active area and a field area. For example, the active area has a substantially flat upper surface. Additionally, the substrate 100 may include a first region A, e.g., a region including the first transistor T1, and a second region B, e.g., a region including the second transistor T2.

The first transistor T1 may include a first gate structure 120 and a first source/drain 132. The first gate structure 120 may include a first gate insulating layer pattern 112, a first conductive layer pattern 114, a first polysilicon layer pattern 116, and a second conductive layer pattern 118.

The first gate insulating layer pattern 112 may be on the substrate 100, and may insulate the first conductive layer pattern 114 from the substrate 100. The first gate insulating layer pattern 112 may include, e.g., a silicon dioxide (SiO₂), a silicon oxynitride (SiON), a metal oxide, and/or a high-K material.

Examples of metal oxides in the first gate insulating layer pattern 112 may include a hafnium oxide, e.g., hafnium oxide (HfO₂), hafnium oxynitride (HfON), hafnium silicon oxide (HfSiO), hafnium silicon oxynitride (HfSiON), hafnium aluminum oxide (HfAlO), hafnium aluminum oxynitride (HfAlON), hafnium lanthanum oxide (HfLaO), hafnium lanthanum oxynitride (HfLaON), and so forth, a zirconium oxide, e.g., zirconium oxide (ZrO₂), zirconium oxynitride (ZrON), zirconium silicon oxynitride (ZrSiON), zirconium silicon oxide (ZrSiO), and so forth, and/or a metal oxide including at least one lanthanide, e.g., lanthanum oxide (La₂O₃), praseodymium oxide (Pr₂O₃), and/or dysprosium oxide (Dy₂O₃). The first gate insulating layer pattern 112 may have a multi-stack structure of the above materials.

Examples of high-K materials in the first gate insulating layer pattern 112 may include lead zirconate titanate (Pb(ZrₓTi₁₋ₓ)O₃; PZT), bismuth lanthanum titanate (Bi₄₋ₓLaₓTi₃O₁₂; BLT), strontium bismuth tantalite (SrBi2Ta₂O₉; SBT), bismuth titanate (Bi₄Ti₃O₁₂; BIT), barium strontium titanate (Ba₁₋ₓSrₓTiO₃; BST), strontium bismuth barium tantalate (SrBi2Ta₂O₉; SBTN), and/or lead lanthanum zirconate-titanate ((Pb, La)(Zr, Ti)O₃; PLZT). The first gate insulating layer pattern 112 may have a multi-stack structure of the above materials.

The first conductive layer pattern 114 of the first gate structure 120 may be formed on the first gate insulating layer pattern 112 by, e.g., a physical vapor deposition (PVD) process, a chemical vapor deposition (CVD) process, or an atomic layer deposition (ALD) process. The first conductive layer pattern 114 may include a metal, e.g., titanium (Ti), tungsten (W), tantalum (Ta), and/or rubidium (Ru), and/or a metal nitride, e.g., tantalum nitride (TaN), tungsten nitride (WN), titanium nitride (TiN), hafnium nitride (HfN), hafnium silicon nitride (HfSiN), titanium silicon nitride (TiSiN), tantalum silicon nitride (TaSiN), and/or hafnium aluminum nitride (HfAlN).

A thickness of the first conductive layer pattern 114 may be adjusted, such that the first conductive layer pattern 114 may have a work function of about 4.3 eV to about 4.7 eV. For example, the first conductive layer pattern 114 may be formed of titanium nitride to a thickness of about 30 angstroms to have a work function of about 4.3 eV to about 4.7 eV.

The first conductive layer pattern 114 may be formed between the first insulation layer pattern 112. Accordingly, the first conductive layer pattern 114 may reduce the depletion of the first polysilicon layer pattern 116 and may increase the on-current. Additionally, the first gate structure 120 may have an effective work function, e.g., suitable for a DRAM device, by adjusting the thickness of the first conductive layer pattern 114.

The first polysilicon layer pattern 116 of the first gate structure 120 may include a polysilicon layer doped with first impurities having a first conductivity type. For example, the first impurities may have a N-type conductivity, and may include, e.g., nitride (N), phosphorous (P), and/or arsenic (As). If the first polysilicon layer includes impurities of N-type conductivity, penetration of impurities, e.g., impurities having P-type conductivity, from the first polysilicon pattern 116 into underlying layers, e.g., the first gate insulating layer 112, and the substrate 100 may be prevented or substantially minimized. It is noted that the conductivity type of the first impurities may not determine whether the first transistor T1 is a NMOS transistor or a PMOS transistor. The first polysilicon layer pattern 116 may have a first doping concentration.

The second conductive layer pattern 118 of the first gate structure 120 may be formed on the first polysilicon layer pattern 116. The second conductive layer pattern 118 may include a material, such that a resistance of the second conductive layer pattern 118 may be lower than a resistance of the first polysilicon layer pattern 116. For example, the second conductive layer pattern 118 may include a metal, e.g., tungsten (W), or a metal silicide, e.g., tungsten silicide (WSi).

The first source/drain 132 of the first transistor T1 may be formed at an upper portion of the substrate 100 in the first region A, and may be adjacent to the first gate structure 120 including the first gate insulating layer pattern 112, the first conductive layer pattern 114, the first polysilicon layer pattern 116, and the second conductive layer pattern 118. The first source/drain 132 may be formed in a portion of the first region A exposed by the first gate structure 120, e.g., the first source/drain 132 may not overlap with the first gate structure 120, and may include second impurities having a second conductivity type. The second conductivity type of the second impurities may or may not be different from the first conductivity type of the first impurities, and may determine the type of the first transistor T1. For example, when the second impurities have a N-type conductivity, the first transistor T1 may function as a NMOS transistor. Similarly, when the second impurities have a P-type conductivity, e.g., boron (B), the first transistor T1 may function as a PMOS transistor. It is noted that the first doping concentration of the first impurities in the first polysilicon layer pattern 116 may affect whether the first transistor T1 functions as a NMOS transistor or as a PMOS transistor.

A mask 110 may be formed on the first gate structure 120 to protect the first gate structure 120. Additionally, a spacer (not shown) may be formed on a sidewall of the first gate structure 120.

The second transistor T2 may be in the second region B of the substrate 100, and may include a second gate structure 130 and a second source/drain 134. The second gate structure 130 may include a second gate insulating layer pattern 122, a third conductive layer pattern 124, a second polysilicon layer pattern 126, and a fourth conductive layer pattern 128.

The second gate insulating layer pattern 122 may be formed on the second region B of the substrate 100. The second gate insulating layer pattern 122 may include a substantially same material as the first gate insulating layer pattern 112 of the first transistor T1.

The third conductive layer pattern 124 of the second gate structure 130 may be formed on the second gate insulating layer pattern 122. The third conductive layer pattern 124 may include a substantially same material as the first conductive layer pattern 114 of the first transistor T1. Additionally, the third conductive layer pattern 124 may have a substantially same thickness as the first conductive layer pattern 114, so the first and third conductive layer patterns 114 and 124 may have a substantially same work function.

The second polysilicon layer pattern 126 may be formed on the third conductive layer pattern 124. The second polysilicon layer pattern 126 may include third impurities having a third conductivity type, and may have a second doping concentration of the third impurities. The third conductivity type may be substantially the same as the first conductivity type. The second doping concentration of the third impurities may be substantially similar to the first doping concentration of the first impurities in the first polysilicon layer pattern 116. Alternatively, the second doping concentration of the third impurities may be different from the first doping concentration of the first impurities in the first polysilicon layer pattern 116. For example, when the first transistor T1 including the first polysilicon layer pattern 116 functions as a PMOS transistor and the second transistor T2 including the second polysilicon layer pattern 126 functions as an NMOS transistor, the second doping concentration of the third impurities having an N-type conductivity may be higher than the first doping concentration of the first impurities having an N-type conductivity.

The fourth conductive layer pattern 128 of the second gate structure 130 may be formed on the second polysilicon layer pattern 126. The fourth conductive layer pattern 128 may include a substantially same material as the second conductive layer pattern 118 of the first transistor T1.

The second source/drain 134 of the second transistor T2 may be formed at an upper portion of the substrate 100 in the second region B, and may be adjacent to the second gate structure 130 including the second gate insulating layer pattern 122, the third conductive layer pattern 124, the second polysilicon layer pattern 126, and the fourth conductive layer pattern 128. The second source/drain 134 may include fourth impurities having a fourth conductivity type. The fourth conductive type may be opposite to the second conductivity type, and may determine the type of the second transistor T2. For example, when the fourth impurities have N-type conductivity, the second transistor T2 may function as a NMOS transistor. Similarly, when the fourth impurities have P-type conductivity, the second transistor T2 may function as a PMOS transistor.

The mask 110 may be formed on the second gate structure 130 and protect the second gate structure 130. Additionally, a spacer (not shown) may be formed on a sidewall of the second gate structure 130.

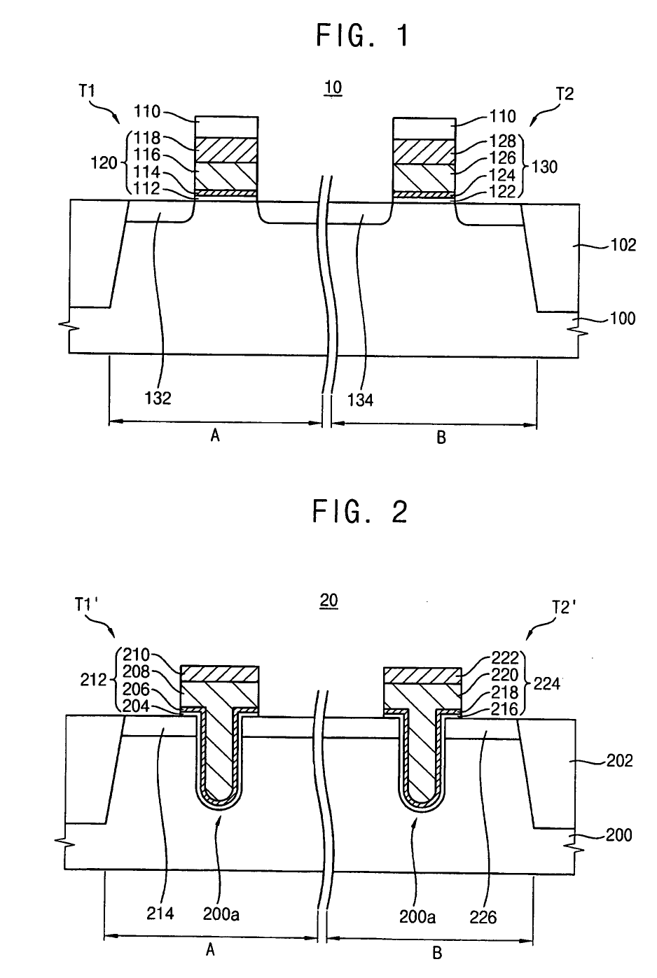

FIG. 2 illustrates a cross-sectional view of a semiconductor device in accordance with another embodiment of the present invention. Referring to FIG. 2, a semiconductor device 20 may include a substrate 200, a first transistor T1′, and a second transistor T2′. The first and second transistors T1′ and T2′ may have recessed channel structure, as further illustrated in FIG. 2.

The substrate 200 may be any suitable semiconductor substrate, e.g., a substrate including silicon or germanium, a SOI substrate, or a GOI substrate. The substrate 200 may include an isolation layer 202 and a recess 200a. The isolation layer 202 may divide the substrate 200 into an active area and a field area, and the recess 200a may be formed at an upper portion of the active area of the substrate 200, i.e., may extend from an upper surface of the substrate 200 in a downward direction toward a bottom surface of the substrate 200. Additionally, the substrate 200 may include a first region A, e.g., a region including the first transistor T1′, and a second region B, e.g., a region including the second transistor T2′.

The first transistor T1′ may include a first gate structure 212 and a first source/drain 214. The first gate structure 212 may include a first gate insulating layer pattern 204, a first conductive layer pattern 206, a first polysilicon layer pattern 208, and a second conductive layer pattern 210.

The first gate insulating layer pattern 204 may be formed on the substrate 200. In particular, the first gate insulating layer pattern 204 may be continuously formed on inner surfaces of the recess 200a and on portions of the upper surface of the substrate 200. It is noted that the first gate insulating layer pattern 204 may not fill completely the recess 200a. The first gate insulating layer pattern 204 may be formed of a substantially same material as the first gate insulating layer pattern 112 of the semiconductor device 10 described previously with reference o FIG. 1, and therefore, a detailed description thereof will not be repeated.

The first conductive layer pattern 206 of the first gate structure 212 may be formed on the first gate insulating layer pattern 204. In particular, the first conductive layer pattern 206 may be continuously formed on inner surfaces of the recess 200a and on portions of the upper surface of the substrate 200 to coat the first gate insulating layer pattern 204. It is noted that the first conductive layer pattern 206 together with the first gate insulating layer pattern 204 may not fill completely the recess 200a. The first conductive layer pattern 204 may be formed of a substantially same material and to a substantially same thickness as the first conductive layer pattern 114 of the semiconductor device 10 described previously with reference o FIG. 1, and therefore, a detailed description thereof will not be repeated.

The first polysilicon layer pattern 208 of the first gate structure 212 may include a lower portion in the recess 200a and an upper portion protruding above the upper surface of the substrate 200. In particular, the lower portion of the first polysilicon layer pattern 208 may be formed on the first conductive layer pattern 206 to fill the recess 200a and the upper portion of the first polysilicon layer pattern 208 may be formed on the first conductive layer pattern 206 in parallel to the bottom surface of the substrate 200. The first polysilicon layer pattern 208 may be formed of a substantially same material and concentration as the first polysilicon layer pattern 116 of the semiconductor device 10 described previously with reference o FIG. 1, and therefore, a detailed description thereof will not be repeated.

The second conductive layer pattern 210 of the first gate structure 212 may be formed on the first polysilicon layer pattern 208, and may be formed of a substantially same material as the second conductive layer pattern 118 of the semiconductor device 10 described previously with reference o FIG. 1, and therefore, a detailed description thereof will not be repeated.

The first gate insulating layer pattern 204, first conductive layer pattern 206, first polysilicon layer pattern 208, and second conductive layer pattern 210 may be arranged such that the first gate structure 212 may have a T-shape, as illustrated in FIG. 2. For example, an upper portion of the T-shape, i.e., a portion configured in parallel to the bottom surface of the substrate 200, may overlap portions of the source/drain region 214 immediately adjacent to the first gate structure 212, as further illustrated in FIG. 2. Unexplained parts of the first transistor T1′ may be substantially similar to those of the first transistor T1 of the semiconductor device 10 illustrated in FIG. 1, and therefore, their detailed descriptions will not be repeated.

The second transistor T2′, as illustrated in FIG. 2, may include a second gate structure 224 and a second source/drain 226. The second gate structure 224 may include a second gate insulating layer pattern 216, a third conductive layer pattern 218, a second polysilicon layer pattern 220, and a fourth conductive layer pattern 222. The structures and compositions of the second gate structure 224 and second source/drain 226 may be substantially similar to the structures and compositions of the first gate structure 112 and second source/drain 214, respectively, and therefore, their detailed descriptions will not be repeated. The first and second transistors T1′ and T2′ of the semiconductor device 20 may have substantially same effects and advantages as the first and second transistors T1 and T2 of the semiconductor device 10 despite their different structures.

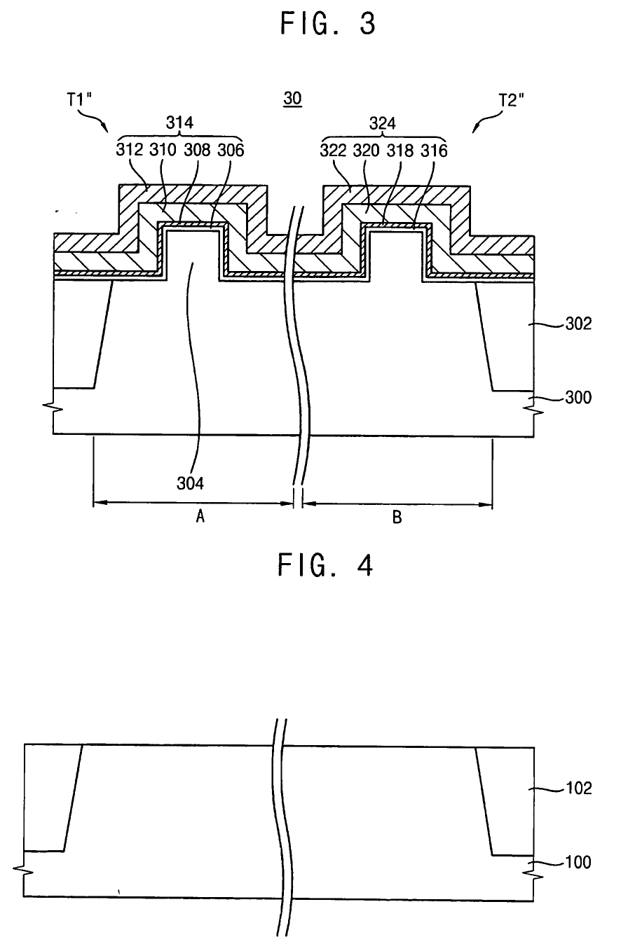

FIG. 3 illustrates a cross-sectional view of a semiconductor device in accordance with another embodiment of the present invention. Referring to FIG. 3, a semiconductor device 30 may include a substrate 300, a first transistor T1″, and a second transistor T2″. The first and second transistors T1″ and T2″ may have a fin-type channel structure, as further illustrated in FIG. 3.

The substrate 300 may be any suitable semiconductor substrate, e.g., a substrate including silicon or germanium, a SOI substrate, or a GOI substrate. The substrate 300 may include an isolation layer 302 and a fin area 304. The isolation layer 302 may divide the substrate 300 into an active area and a field area, and the fin area 304 may protrude from an upper surface of the active area. The fin area 304 may extend from an upper surface of the substrate 300 in a first direction, e.g., an upward direction, away from a bottom surface of the substrate 300. Additionally, the substrate 300 may include a first region A, e.g., a region including the first transistor T1″, and a second region B, e.g., a region including the second transistor T2″.

The first transistor T1″ may include a first gate structure 314 and a first source/drain (not shown). The first gate structure 314 may include a first gate insulating layer pattern 306, a first conductive layer pattern 308, a first polysilicon layer pattern 310, and a second conductive layer pattern 312.

The first gate insulating layer pattern 306 may be formed on the substrate 300. In particular, the first gate insulating layer pattern 306 may be continuously formed on side and upper surfaces of the fin area 304 and on portions of the upper surface of the substrate 300. The first gate insulating layer pattern 306 may be formed on the first region A of the substrate 300, and may extend in a second direction perpendicular to the first direction. The first gate insulating layer pattern 306 may be formed of a substantially same material as the first gate insulating layer pattern 112 of the semiconductor device 10 described previously with reference o FIG. 1, and therefore, a detailed description thereof will not be repeated.

The first conductive layer pattern 308 of the first gate structure 314 may be formed on the first gate insulating layer pattern 306. For example, the first conductive layer pattern 308 may be continuously formed on the first gate insulating layer pattern 306 to cover upper surfaces thereof, i.e., surfaces facing away from the substrate 300, and may extend in the second direction. The first conductive layer pattern 308 may be formed of a substantially same material and to a substantially same thickness as the first conductive layer pattern 114 of the semiconductor device 10 described previously with reference o FIG. 1, and therefore, a detailed description thereof will not be repeated.

The first polysilicon layer pattern 310 of the first gate structure 314 may be formed on the first conductive layer pattern 308, and may extend in the second direction. The second conductive pattern 314 may be formed on the first polysilicon layer pattern 310. The first source/drain may be formed on a portion of the fin area 304 exposed by the first gate structure 314.

For example, the first gate insulating layer pattern 306, first conductive layer pattern 308, first polysilicon layer pattern 310, and second conductive layer pattern 312 may be arranged to completely overlap each other such that the first gate structure 314 may have a step-shape, as illustrated in FIG. 3. Unexplained parts of the first transistor T1″, e.g., composition, additional elements, and so forth, may be substantially similar to those of the first transistor T1 of the semiconductor device 10 illustrated in FIG. 1, so detailed descriptions thereof are omitted.

The second transistor T2″, as illustrated in FIG. 3, may include a second gate structure 324 and a second source/drain (not shown). The second gate structure 324 may include a second gate insulating layer pattern 316, a third conductive layer pattern 318, a second polysilicon layer pattern 320, and a fourth conductive layer pattern 322. The structures and compositions of the second gate structure 324 and second source/drain may be substantially similar to the structures and compositions of the first gate structure 314 and a second source/drain, respectively, and therefore, their detailed descriptions will not be repeated. The first and second transistors T1″ and T2″ of the semiconductor device 30 may have substantially same effects and advantages as the first and second transistors T1 and T2 of the semiconductor device 10 despite their different structures.

Hereinafter, an exemplary method of manufacturing semiconductor devices according to example embodiments of the present invention will be described in detail. FIGS. 4-9 illustrate cross-sectional views of sequential stages in a method of manufacturing the semiconductor device 10 of FIG. 1.

Referring to FIG. 4, the isolation layer pattern 102 may be formed on the substrate 100. The substrate 100 may be a semiconductor substrate, e.g., a substrate including silicon or germanium, a SOI substrate, or a GOI substrate.

Hereinafter, a process for forming the isolation layer pattern 102 will be described in detail. First, a pad oxide layer (not shown) may be formed on the substrate 100, followed by formation of a first mask pattern (not shown) on the pad oxide layer. The pad oxide layer may mitigate stress between the substrate 100 and the first mask pattern (not shown), and may be formed by, e.g., a thermal oxidation process or a CVD process, using, e.g., a silicon oxide. The first mask pattern may be formed on the pad oxide layer by, e.g., a CVD process, using, e.g., a nitride.

Then, the pad oxide layer and the substrate 100 may be etched using the first mask pattern as an etch mask to form a pad oxide layer pattern (not shown) and a trench (not shown). The etching process may include, e.g., an anisotropic plasma etching process.

A thermal oxide layer (not shown) may be formed on inner sidewalls of the trench in order to minimize and/or cure damage thereto, e.g., damage to the inner sidewalls of the trench due to plasma etching. A liner layer (not shown) including, e.g., a nitride, may be continuously formed on inner sidewalls of the trench, e.g., on the thermal oxide layer, and on the first mask pattern. The liner layer may mitigate stress between the trench and an isolation layer (not shown) therein formed in a subsequent process, and may prevent impurity penetration from the source/drain 132 and 134 of the first and second transistors T1 and T2 into the substrate 100.

The isolation layer may be formed on the first mask pattern to fill the trench. Then, an upper surface of the isolation layer may be planarized to expose an upper surface of the first mask pattern, such that a portion of the isolation layer remaining in the trench may define the isolation layer pattern 102. The planarization process may include, e.g., a chemical mechanical polishing (CMP) process, an etch-back process, or a combination thereof. The isolation layer pattern 102 may expose a sidewall of the first mask pattern. An upper surface of the isolation layer pattern 102 may be substantially level with an upper surface of the substrate 100, as illustrated in FIG. 4. After forming the isolation layer pattern 102, the first mask pattern may be removed.

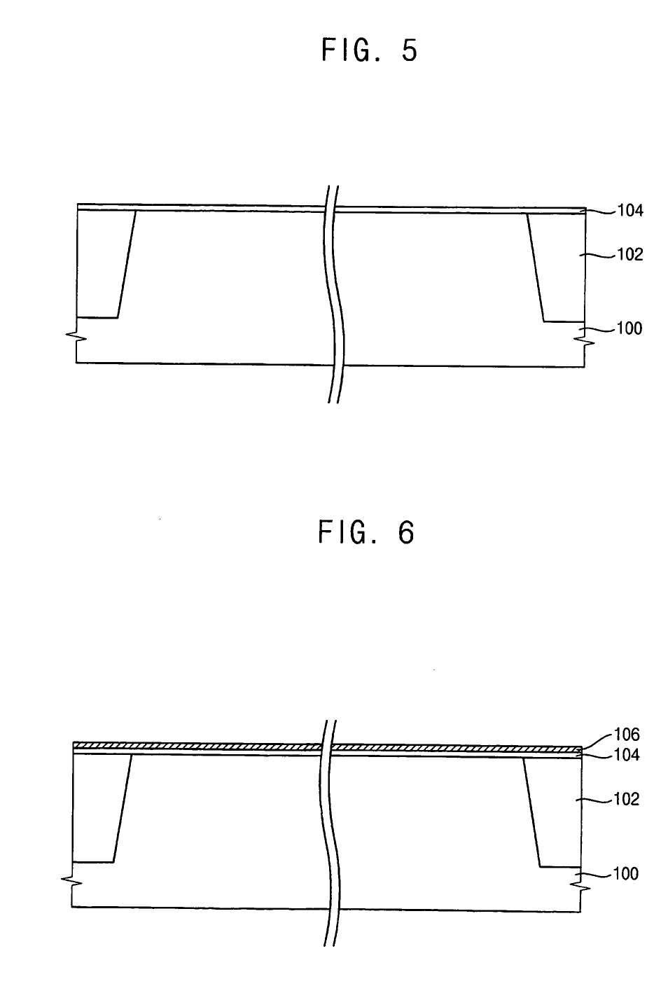

Referring to FIG. 5, a gate insulating layer 104 may be formed on the first and second regions A and B of the substrate 100. For example, the gate insulating layer 104 may be formed by depositing a silicon oxide or silicon oxynitride by, e.g., a thermal oxidation process or a CVD process. In another example, the gate insulating layer 104 may be formed by depositing a metal oxide, e.g., hafnium oxide or zirconium oxide, a metal oxide including at least one lanthanide, and/or a high-K material on the first and second regions A and B of the substrate 100. The first gate insulating layer pattern 112 may have a multi-stack structure of the above materials.

Examples of hafnium oxide may include one or more of hafnium oxide (HfO₂), hafnium oxynitride (HfON), hafnium silicon oxide (HfsiO), hafnium silicon oxynitride (HfSiON), hafnium aluminum oxide (HfAlO), hafnium aluminum oxynitride (HfAlON), hafnium lanthanum oxide (HfLaO), and hafnium lanthanum oxynitride (HfLaON). Examples of zirconium oxide may include one or more of zirconium oxide (ZrO₂), zirconium oxynitride (ZrON), zirconium silicon oxynitride (ZrSiON), and zirconium silicon oxide (ZrSiO). Examples of lanthanides may include one or more of lanthanum oxide (La₂O₃), praseodymium oxide (Pr₂O₃), and dysprosium oxide (Dy₂O₃). Examples of high-K materials may include one or more of lead zirconate titanate (Pb(ZrₓTi₁₋ₓ)O₃; PZT), bismuth lanthanum titanate (Bi₄₋ₓLaₓTi₃O₁₂; BLT), strontium bismuth tantalite (SrBi2Ta₂O₉; SBT), bismuth titanate (Bi₄Ti₃O₁₂; BIT), barium strontium titanate (Ba₁₋ₓSrₓTiO₃; BST), strontium bismuth barium tantalate (SrBi2Ta₂O₉; SBTN), and lead lanthanum zirconate-titanate ((Pb, La)(Zr, Ti)O₃; PLZT).

Referring to FIG. 6, the first conductive layer 106 may be formed on the gate insulating layer 104 by, e.g., a CVD process, a PVD process, or an ALD process. For example, the first conductive layer 106 may be formed of a metal, e.g., titanium (Ti), tungsten (W), tantalum (Ta), or rubidium (Ru), a metal nitride, e.g., tantalum nitride (TaN), tungsten nitride (WN), hafnium nitride (HfN), hafnium silicon nitride (HfSiN), titanium silicon nitride (TiSiN), tantalum silicon nitride (TaSiN), or hafnium aluminum nitride (HfAlN).

The thickness of the first conductive layer 106 may be adjusted, such that the first conductive layer 106 may have a work function of about 4.3 eV to about 4.7 eV. For example, when the first conductive layer 106 includes titanium nitride and has a thickness of about 30 angstroms, the first conductive layer 106 may have a work function of about 4.3 eV to about 4.7 eV.

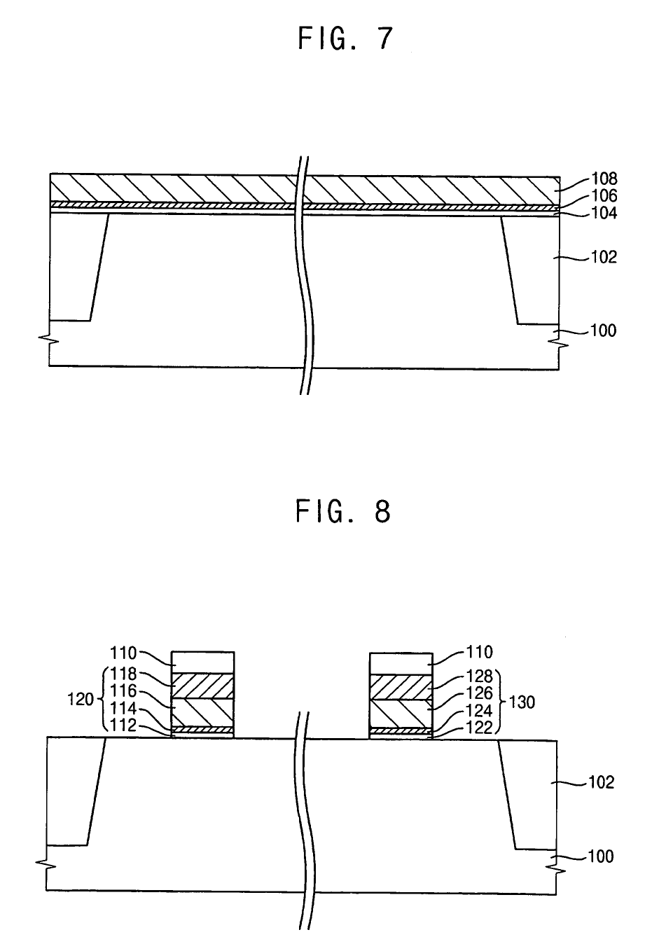

Referring to FIG. 7, a polysilicon layer 108 may be formed on the first conductive layer 106, e.g., on an entire upper surface of the first conductive layer 106. The polysilicon layer 108 may be doped with the first impurities having the first conductive type. For example, the first impurities may have N-type conductivity, and may include, e.g., nitride (N), phosphor (P) or arsenic (As). Use of impurities having N-type conductivity may be advantageous to prevent or substantially minimize impurity penetration. In other words, P-type impurities may penetrate from the polysilicon layer 108 into underlying layers during subsequent processes. However, since the polysilicon layer 108 is doped with impurities having N-type conductivity, the impurity penetration may be prevented or substantially minimized.

A part of the polysilicon layer 108, i.e., a portion positioned in the first region A of the substrate 100, may function as a gate electrode of the first transistor T1, e.g., a PMOS transistor, and a remaining part of the polysilicon layer 108, i.e., a portion positioned in the second region B of the substrate 100, may function as a gate electrode of the second transistor T2, e.g., a NMOS transistor. Thus, since conductivity type of the impurities in the polysilicon layer 108 may be substantially the same both in the first and the second regions A and B of the substrate 100, the conductivity type of the impurities in the polysilicon layer 108 may not determine whether a transistor is a PMOS transistor or a NMOS transistor.

Using a substantially same conductivity type in the entire polysilicon layer 108, i.e., in both first and second regions and A and B of the substrate 100, may simplify manufacturing by eliminating a requirement for a separate and/or an additional impurity doping process. For example, the ion implantation process may require less time, and a proper time delay may be reduced. Additionally, when the polysilicon layer 108, i.e., first and second silicon layer patterns 116 and 126 patterned therefrom, is doped with N-type impurities, impurity penetration caused by the P-type impurities can be prevented, so that the activation temperature may increase.

Although not shown in detail, the first impurity concentration in the polysilicon layer 108 formed on first region A of the substrate 100 may be different from the first impurity concentration of the polysilicon layer 108 formed in the second region B of the substrate 100.

Referring to FIG. 8, a second conductive layer (not shown) may be formed on the polysilicon layer 108. The second conductive layer may have a resistance lower than that of the first polysilicon layer 108. The second conductive layer may be formed of a metal, e.g., W, or of a metal silicide, e.g., WSi.

Then, the mask pattern 110 may be formed on the second conductive layer.

The mask pattern 110 may extend in a direction perpendicular to a direction of the active area. As illustrated in FIG. 8, the second conductive layer, the polysilicon layer 108, the first conductive layer 106, and the gate insulating layer 104 may be partially etched using the second mask pattern 110 as an etch mask to form the first and second gate structures 120 and 130 on the substrate 100.

That is, the first gate structure 120 may be formed on the first region A of the substrate 100, which includes the first gate insulating layer pattern 112, the first conductive layer pattern 114, the first polysilicon layer pattern 116, and the second conductive layer pattern 118 sequentially stacked on the substrate 100. The second gate structure 130 may be formed on the second region B of the substrate 100, which includes the second gate insulating layer pattern 122, the third conductive layer pattern 124, the second polysilicon layer pattern 126, and the fourth conductive layer pattern 128 sequentially stacked on the substrate 100.

It is noted that formation of the first and third conductive layer patterns 114 and 124 below the first and second polysilicon layer patterns 116 and 126, respectively, may be advantageous in preventing or substantially minimizing formation of a depletion region in the first and second polysilicon layer patterns 116 and 126, and in increasing an on-current. For example, when the first transistor T1 including the first conductive layer pattern 114 or the second transistor T2 including the third conductive layer pattern 124 functions as a PMOS transistor, formation of a depletion region in a respective polysilicon layer pattern may be reduced by about 30% or more, as compared to that of a transistor including no conductive layer pattern below a respective polysilicon layer pattern.

The first gate insulating layer pattern 112 may include a substantially same material as the second gate insulating layer pattern 122, the first conductive layer pattern 114 may include a substantially same material as the third conductive layer pattern 124, the first polysilicon layer pattern 116 may be doped with impurities having substantially same conductivity as the impurities of the second polysilicon layer pattern 126, and the second conductive layer pattern 118 may include a substantially same material as the fourth conductive layer pattern 128. The doping concentration of the first polysilicon layer pattern 116 may be different from that of the second polysilicon layer pattern 126.

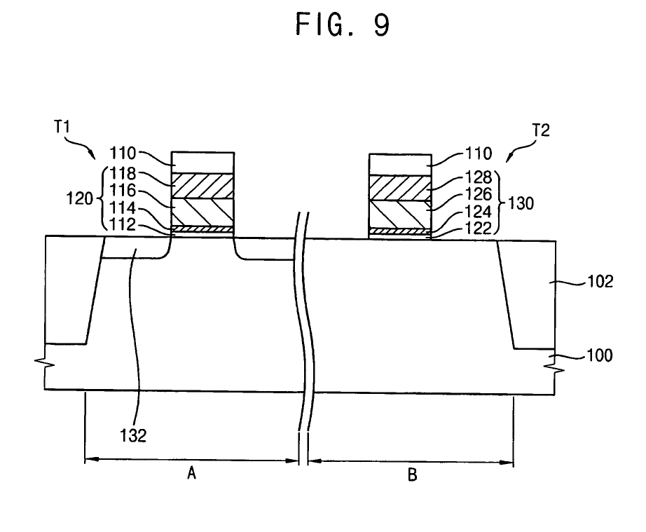

Referring to FIG. 9, the second impurities having the second conductivity type may be implanted onto an upper portion of the substrate 100 in the first region A thereof. The second impurities in the substrate 100 may define the first source/drain 132, and may define whether the first transistor T1 is a NMOS transistor or a PMOS transistor.

Similarly, the fourth impurities having a conductivity opposite the second conductivity may be implanted onto an upper portion of the substrate 100 in the second region B thereof. The fourth impurities in the substrate 100 may define the second source/drain 134 illustrated in FIG. 1, and may define whether the second transistor T2 is a NMOS transistor or a PMOS transistor. Thus, the first transistor T1 may be formed on the first region A of the substrate 100 and the second transistor T2 may be formed on the second region B of the substrate 100. Further, since the second and fourth impurities may have opposite conductivities, the first and second transistor T1 and T2 may form a CMOS.

Semiconductor devices according to example embodiments of the present invention may be advantageous in using substantially same conductivity type impurities in first and second polysilicon layer patterns, thereby reducing ion implantation time and time delay, and simplifying overall manufacturing process. Additionally, semiconductor devices according to example embodiments of the present invention may be advantageous in providing a conductive layer between the substrate and a respective polysilicon layer pattern, thereby reducing formation of depletion regions in the polysilicon layer patterns and increasing on-current. Further, semiconductor devices according to example embodiments of the present invention may be advantageous in providing silicon layer patterns with N-type impurities, thereby preventing or substantially minimizing impurity penetration caused by P-type impurities to increase the activation temperature.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
a first gate structure on a first region of a substrate, the first gate structure including
a first insulating layer pattern on the substrate,
a first conductive layer pattern on the first insulating layer pattern, and
a first polysilicon layer pattern on the first conductive layer pattern, the first polysilicon layer pattern including first impurities of a first conductivity type;
a first source/drain in the first region of the substrate, the first source/drain including second impurities of a second conductivity type;
a second gate structure on a second region of the substrate, the second gate structure including
a second insulating layer pattern on the substrate,
a second conductive layer pattern on the second insulating layer pattern, the second conductive layer pattern including a substantially same material as the first conductive layer pattern, and
a second polysilicon layer pattern on the second conductive layer pattern, the second polysilicon layer pattern including third impurities with the first conductivity type; and
a second source/drain in the second region of the substrate, the second source/drain including fourth impurities having a conductivity type opposite the second conductivity.

2. The semiconductor device as claimed in claim 1, wherein the first and second conductive layer patterns exhibit a work function in a range of about 4.3 eV to about 4.7 eV.

3. The semiconductor device as claimed in claim 1, wherein the first and second conductive layer patterns include a metal.

4. The semiconductor device as claimed in claim 3, wherein the first and second conductive layer patterns include titanium (Ti), tungsten (W), tantalum (Ta), or rubidium (Ru).

5. The semiconductor device as claimed in claim 1, wherein the first and second conductive layer patterns include a metal silicide.

6. The semiconductor device as claimed in claim 5, wherein the first and second conductive layer patterns include tantalum nitride (TaN), tungsten nitride (WN), titanium nitride (TiN), hafnium nitride (HfN), hafnium silicon nitride (HfSiN), titanium silicon nitride (TiSiN), tantalum silicon nitride (TaSiN), or hafnium aluminum nitride (HfAlN).

7. The semiconductor device as claimed in claim 1, wherein a concentration of the first impurities in the first polysilicon layer is different from a concentration of the third impurities in the second polysilicon layer pattern.

8. The semiconductor device as claimed in claim 1, wherein the first and second insulating layer patterns include a substantially same material.

9. The semiconductor device as claimed in claim 8, wherein the first and second insulating layer patterns include silicon dioxide (SiO₂) and/or silicon oxynitride (SiON).

10. The semiconductor device as claimed in claim 8, wherein the first and second insulating layer patterns include hafnium oxide and/or zirconium oxide.

11. The semiconductor device as claimed in claim 10, wherein the first and second insulating layer patterns include one or more of hafnium oxide (HfO₂), hafnium oxynitride (HfON), hafnium silicon oxide (HfSiO), hafnium silicon oxynitride (HfSiON), hafnium aluminum oxide (HfAlO), hafnium aluminum oxynitride (HfAlON), hafnium lanthanum oxide (HfLaO), hafnium lanthanum oxynitride (HfLaON), zirconium oxide (ZrO₂), zirconium oxynitride (ZrON), zirconium silicon oxynitride (ZrSiON), and zirconium silicon oxide (ZrSiO).

12. The semiconductor device as claimed in claim 8, wherein the first and second insulating layer patterns include a metal oxide, the metal oxide being a lanthanide.

13. The semiconductor device as claimed in claim 12, wherein the first and second insulating layer patterns include one or more of lanthanum oxide (La₂O₃), praseodymium oxide (Pr₂O₃), and dysprosium oxide (Dy₂O₃).

14. The semiconductor device as claimed in claim 8, wherein the first and second insulating layer patterns include one or more of lead zirconate titanate (Pb(ZrₓTi₁₋ₓ)O₃; PZT), bismuth lanthanum titanate (Bi₄₋ₓLaₓTi₃O₁₂; BLT), strontium bismuth tantalite (SrBi2Ta₂O₉; SBT), bismuth titanate (Bi₄Ti₃O₁₂; BIT), barium strontium titanate (Ba₁₋ₓSrₓTiO₃; BST), strontium bismuth barium tantalate (SrBi2Ta₂O₉; SBTN), and lead lanthanum zirconate-titanate ((Pb, La)(Zr, Ti)O₃; PLZT).

15. The semiconductor device as claimed in claim 1, further comprising third and fourth conductive layer patterns on the first and second gate structures, respectively.

16. The semiconductor device as claimed in claim 15, wherein the third and fourth conductive layer patterns include a material having a lower resistance than a resistance of the first and second polysilicon layer patterns.

17. A method of manufacturing a semiconductor device, the method comprising:
forming a first gate structure on a first region of a substrate, the first gate structure including sequentially stacked a first insulating layer pattern, a first conductive layer pattern, and a first polysilicon layer pattern, the first polysilicon layer pattern including first impurities of a first conductivity type;
forming a first source/drain in the first region of the substrate, the first source/drain including second impurities of a second conductivity type;
forming a second gate structure on a second region of the substrate, the second gate structure including sequentially stacked a second insulating layer pattern, a second conductive layer pattern having a substantially same material as the first conductive layer pattern, and a second polysilicon layer pattern, the second polysilicon pattern including third impurities of the first conductivity type; and
forming a second source/drain in the second region of the substrate, the second source/drain including fourth impurities having a conductivity type opposite the second conductivity.

18. A method of manufacturing a semiconductor device, the method comprising:
forming an insulating layer, a conductive layer and a polysilicon layer on a substrate including first and second regions, the polysilicon layer including first impurities of a first conductivity type;
partially etching the polysilicon layer, the conductive layer and the insulating layer to form first and second gate structures on the first and second regions of the substrate, respectively, the first gate structure having a first insulating layer pattern, a first conductive layer pattern and a first polysilicon layer pattern sequentially stacked, and the second gate structure having a second insulating layer pattern, a second conductive layer pattern and a second polysilicon layer pattern sequentially stacked;
forming a first source/drain by doping second impurities of a second conductivity type onto the first region of the substrate exposed by the first gate structure; and
forming a second source/drain by doping third impurities onto the second region of the substrate exposed by the second gate structure, the third impurities having a conductivity type opposite the second conductivity.

19. The method as claimed in claim 18, wherein the conductive layer is formed to have a work function in a range of about 4.3 eV to about 4.7 eV.

20. The method as claimed in claim 18, wherein the conductive layer is formed by a physical vapor deposition (PVD) process, a chemical vapor deposition (CVD) process, or an atomic layer deposition (ALD) process.
